(19) United States
(12) Patent Application Publication
(10) Pub. No.: US 2026/0096496 A1
(43) Pub. Date: Apr. 2, 2026

(54) INTEGRATED DEVICE WITH MULTIPLE ARRAYS OF OFF-PACKAGE INTERCONNECTS

(71) Applicant: QUALCOMM Incorporated, San Diego, CA (US)

(72) Inventors: Aniket PATIL, San Diego, CA (US); Manuel ALDRETE, Encinitas, CA (US); Joan Rey Villarba BUOT, Escondido, CA (US)

(21) Appl. No.: 18/904,982

(22) Filed: Oct. 2, 2024

(51) Int. Cl. H01L 23/498; H01L 21/48

(52) U.S. Cl. CPC H10W 90/701; H10W 70/093; H10W 70/69

(57) ABSTRACT

An integrated device includes one or more dies and a substrate. The substrate includes on-package contacts coupled to the one or more dies and off-package contacts configured to be coupled to a printed circuit board (PCB). The integrated device also includes a first set of electrical interconnects electrically coupled to a first subset of the off-package contacts and that form a ball grid array (BGA). The integrated device also includes a second set of electrical interconnects electrically coupled to a second subset of the off-package contacts and that form a land grid array (LGA).

### FIELD

Various features relate to integrated circuit devices with multiple arrays of interconnects.

### DESCRIPTION OF RELATED ART

Electrical connections exist at each level of a system hierarchy. This system hierarchy includes interconnection of active devices at a lowest system level all the way up to system level interconnections at the highest level. For example, interconnect layers can connect different devices together on an integrated circuit. As integrated circuits become more complex, more interconnect layers are used to provide the electrical connections between the devices. More recently, the number of interconnect levels for circuitry has substantially increased due to the large number of devices that are now interconnected in a modern electronic device. The increased number of interconnect levels for supporting the increased number of devices involves more intricate processes.

In state-of-the-art electronic devices, there is generally an expectation that integrated device packages have a small form factor, a low cost, a tight power budget, and high performance. These various goals are often in conflict. For example, the increasing number of interconnects that provide ground, power, or signal routing to integrated circuits provides more advanced die functionality, which improves performance and user experience. However, the increasing number of interconnects can drive increases in the size of integrated device packages due to the need to provide more ground, power, or signal paths to support die functionality. For example, due to design rules for package-to-printed circuit board connections, interconnect density for an array of interconnects on a package substrate may be constrained and thus unable to match an increased interconnect density on a die without requiring a larger package substrate.

### SUMMARY

Various features relate to integrated circuit devices.

One example provides an integrated device that includes one or more dies and a substrate. The substrate includes on-package contacts coupled to the one or more dies and off-package contacts configured to be coupled to a printed circuit board (PCB). The integrated device also includes a first set of electrical interconnects electrically coupled to a first subset of the off-package contacts and that form a ball grid array (BGA). The integrated device also includes a second set of electrical interconnects electrically coupled to a second subset of the off-package contacts and that form a land grid array (LGA).

Another example provides a method of fabrication that includes forming a first set of conductive structures extending from a first subset of off-package contacts of a substrate. The substrate includes the off-package contacts and on-package contacts. The method also includes electrically coupling a first set of electrical interconnects to a second subset of the off-package contacts to form a BGA. The method also includes electrically coupling a second set of electrical interconnects to the first set of conductive structures to form an LGA.

Another example provides a device that includes one or more dies, a PCB, and a substrate disposed between the one or more dies and the PCB. The substrate includes on-package contacts coupled to the one or more dies and off-package contacts coupled to the PCB. The device also includes a first set of electrical interconnects electrically coupled to a first subset of the off-package contacts and to the PCB and that form a BGA. The device also includes a second set of electrical interconnects electrically coupled to a second subset of the off-package contacts and to the PCB and that form an LGA.

### BRIEF DESCRIPTION OF THE DRAWINGS

Various features, nature and advantages may become apparent from the detailed description set forth below when taken in conjunction with the drawings in which like reference characters identify correspondingly throughout. It is noted that one or more figures are annotated with X-, Y-, and/or Z-axes to facilitate recognition of the orientation illustrated in each view.

FIG. 1A illustrates a bottom view of an exemplary substrate that includes multiple arrays of off-package interconnects.

FIG. 1B illustrates a cross-sectional profile view of the exemplary substrate of FIG. 1A.

FIG. 2 illustrates a bottom view of another exemplary substrate that includes multiple arrays of off-package interconnects.

FIG. 3A illustrates a first stage during panel level fabrication of an exemplary substrate that includes multiple arrays of off-package interconnects.

FIG. 3B illustrates a second stage during panel level fabrication of an exemplary substrate that includes multiple arrays of off-package interconnects.

FIG. 4 illustrates a cross-sectional profile view of a particular implementation of a device that includes an exemplary substrate that includes multiple arrays of off-package interconnects.

FIG. 5A illustrates a first part of an exemplary sequence for fabricating an exemplary device that includes a substrate that includes multiple arrays of off-package interconnects.

FIG. 5B illustrates a second part of an exemplary sequence for fabricating an exemplary device that includes a substrate that includes multiple arrays of off-package interconnects.

FIG. 5C illustrates a third part of an exemplary sequence for fabricating an exemplary device that includes a substrate that includes multiple arrays of off-package interconnects.

FIG. 6 illustrates an exemplary flow diagram of a method of fabrication for a device that includes a substrate that includes multiple arrays of off-package interconnects.

FIG. 7 illustrates various electronic devices that may integrate an exemplary device that includes a substrate that includes multiple arrays of off-package interconnects described herein.

### DETAILED DESCRIPTION

In the following description, specific details are given to provide a thorough understanding of the various aspects of the disclosure. However, it will be understood by one of ordinary skill in the art that the aspects may be practiced without these specific details. For example, circuitry may be shown in block diagrams in order to avoid obscuring the aspects in unnecessary detail. In other instances, well-known circuits, structures and techniques may not be shown in detail in order not to obscure the aspects of the disclosure. As another example, various devices and structures disclosed herein are illustrated schematically. Such schematic representations are not to scale and are generally intentionally simplified. To illustrate, integrated devices can have many tens or hundreds of contacts and corresponding interconnections; however, a very small number of such contacts and interconnects are illustrated herein to highlight important features of the disclosure without unduly complicating the drawings.

Particular aspects of the present disclosure are described below with reference to the drawings. In the description, common features are designated by common reference numbers. As used herein, various terminology is used for the purpose of describing particular implementations only and is not intended to be limiting of implementations. For example, the singular forms “a,” “an,” and “the” are intended to include the plural forms as well, unless the context clearly indicates otherwise. Further, some features described herein are singular in some implementations and plural in other implementations. For ease of reference herein, such features are generally introduced as “one or more” features and are subsequently referred to in the singular or optional plural (as indicated by “(s)”) unless aspects related to multiple of the features are being described.

In some drawings, multiple instances of a particular type of feature are shown. In some circumstances, fewer than all of such features may be identified using a reference number. For example, a single reference number may be shown and associated with a representative instance of the feature so as not to obscure other aspects of the drawings.

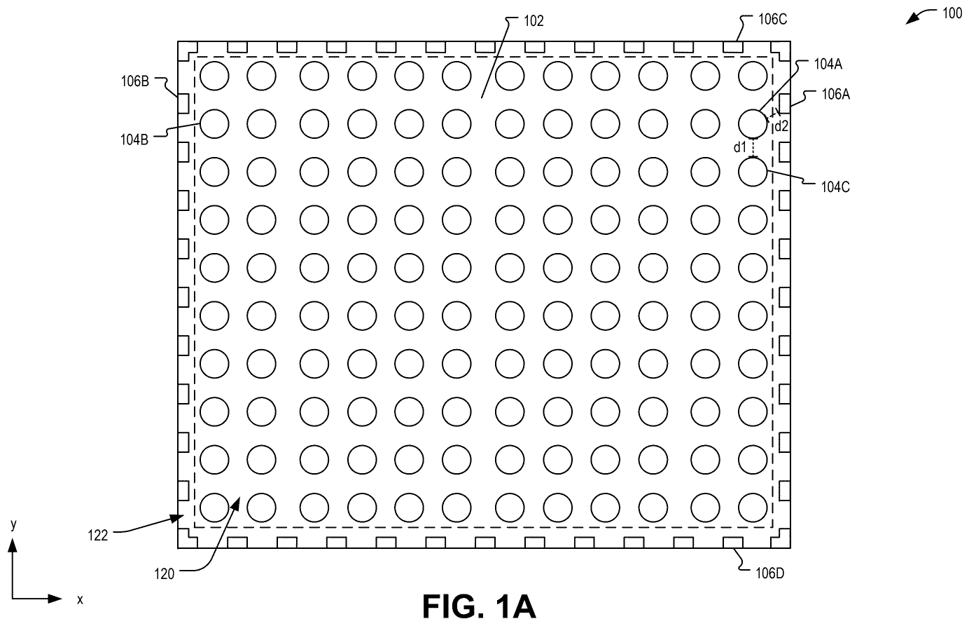

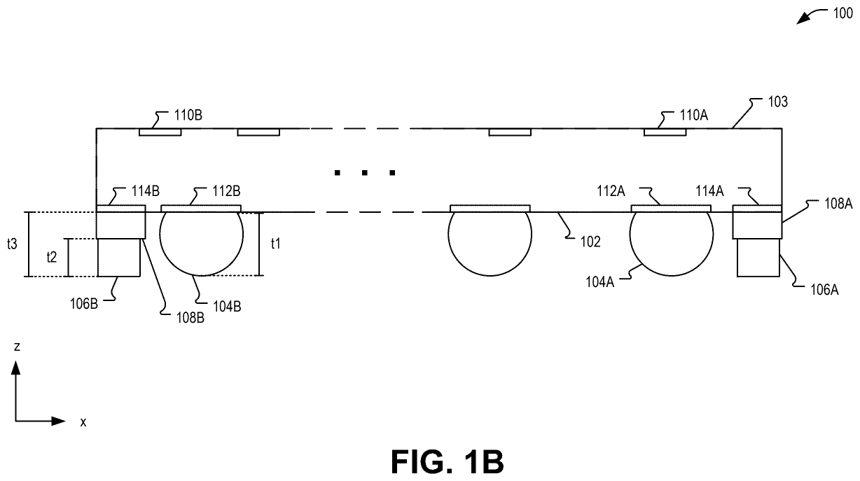

In some drawings in which multiple instances of a particular type of feature are used, different instances are distinguished by addition of a letter to the reference number. In this case, when the features as a group or a type are referred to herein (e.g., when no particular one of the features is being referenced), the reference number is used without a distinguishing letter. However, when one particular feature of multiple features of the same type is referred to herein, the reference number is used with the distinguishing letter. For example, referring to FIG. 1A, multiple interconnects are illustrated and associated with reference numbers 104A and 104B. When referring to a particular one of these interconnects, such as an interconnect 104A, the distinguishing letter “A” is used. However, when referring to any arbitrary one of these interconnects or to these interconnects as a group, the reference number 104 is used without a distinguishing letter.

As used herein, the terms “comprise,” “comprises,” and “comprising” may be used interchangeably with “include,” “includes,” or “including.” As used herein, “exemplary” indicates an example, an implementation, and/or an aspect, and should not be construed as limiting or as indicating a preference or a preferred implementation. As used herein, an ordinal term (e.g., “first,” “second,” “third,” etc.) used to modify an element, such as a structure, a component, an operation, etc., does not by itself indicate any priority or order of the element with respect to another element, but rather merely distinguishes the element from another element having a same name (but for use of the ordinal term). As used herein, the term “set” refers to one or more of a particular element, and the term “plurality” refers to multiple (e.g., two or more) of a particular element.

As used herein, the term “layer” includes a film, and is not construed as indicating a vertical or horizontal thickness unless otherwise stated. As used herein, the term “chiplet” may refer to an integrated circuit block, a functional circuit block, or other like circuit block specifically designed to work with one or more other chiplets to form a larger, more complex chiplet architecture.

Improvements in manufacturing technology and demand for lower cost and more capable electronic devices has led to increasing complexity of integrated circuits (ICs). Often, more complex ICs have more complex interconnection schemes to enable interaction between ICs of a device. The number of interconnect levels for circuitry has substantially increased due to the large number of devices that are now interconnected in a state-of-the-art device.

These interconnections include back-end-of-line (BEOL) interconnect layers, which may refer to the conductive interconnect layers for electrically coupling to front end-of-line (FEOL) active devices of an IC. The various BEOL interconnect layers are formed at corresponding BEOL interconnect levels, in which lower BEOL interconnect levels generally use thinner metal layers relative to upper BEOL interconnect levels. The BEOL interconnect layers may electrically couple to middleof-line (MOL) interconnect layers, which interconnect to the FEOL active devices of an IC.

State-of-the-art electronic devices (e.g., portable computing devices, mobile communication devices, wearable devices, special purpose computing devices, etc.) demand a small form factor, low cost, a tight power budget, and high electrical performance. Integrated circuit package design has evolved to meet these divergent goals. One approach to reducing package size is to integrate multiple dies within a single package.

One example of a multi-die package is a two-dimensional (2D) package architecture, in which two or more dies are coupled to a package substrate side-by-side with one another. A similar approach is a 2.5D architecture, in which two or more devices are positioned side-by-side with one another on the package substrate, and one or more additional devices are stacked on at least one of the side-by-side devices. In each of these architectures, dies can interact with one another (e.g., via die-to-die (D2D) connections) and with off-package devices (e.g., via off-package connections). A challenge of such configurations is that on-package connections, such as D2D connections, and off-package connections have different design criteria. For example, off-package connections are generally larger (e.g., in terms of line width, line spacing, etc.) than is needed for on-package connections. As a result, increasing the number of on-package connections results in a smaller required increase in package size as compared to a similar increase in the number of off-package connections. Furthermore, routing a larger number of connections between off-package components and on-package components increases the complexity of package design.

Aspects of the present disclosure are directed to a substrate (e.g., a package substrate) that includes multiple arrays of off-package interconnects. In some aspects described herein, an integrated device includes a substrate that includes on-package contacts configured to be coupled to one or more dies (or other on-package components) and off-package contacts configured to be coupled to a printed circuit board (PCB). On a particular surface of the substrate (e.g., a bottom surface), different types of electrical interconnects are disposed that each form a respective array. For example, a first set of electrical interconnects (e.g., solder balls) may be electrically coupled to a first subset of the off-package contacts, and a second set of electrical interconnects (e.g., planar solder structures or solder paste) may be electrically coupled to a second subset of off-package contacts. In this example, the first set of electrical interconnects form a ball grid array (BGA) and are disposed within an interior region of the bottom surface of the substrate, and the second set of electrical interconnects form a land grid array (LGA) and are disposed within a peripheral (e.g., outer) region of the bottom surface of the substrate that surrounds the interior region. The second set of electrical interconnects can be configured to provide ground, power, or signal routing to on-package components.

Thus, the disclosed substrate with the multiple arrays of off-package interconnects provides an increased off-package connection density by leveraging space on a package substrate that goes unused in other package substrate designs. As a result, the substrate disclosed herein can provide an increased number of off-package connections as compared to another package substrate having the same size, or the substrate disclosed herein can have a reduced size as compared to another package substrate that provides the same number of off-package connections. An additional benefit of the disclosed substrate and interconnect configuration is that the interconnects that form the LGA in a peripheral region of the bottom surface of the substrate provide additional connections between the package substrate and the PCB, which can reduce or prevent warpage along the edges of the package substrate.

### Exemplary Substrate Including Multiple Arrays of Off-Package Interconnects

FIG. 1A illustrates a bottom view of an exemplary substrate 100 that includes multiple arrays of off-package interconnects. FIG. 1B illustrates a cross-sectional profile view of the exemplary substrate 100 of FIG. 1A.

In the example shown in FIG. 1A, the substrate 100 includes, or is electrically coupled to, interconnects 104 (e.g., a first set of electrical interconnects) and interconnects 106 (e.g., a second set of electrical interconnects). For example, the interconnects 104 may be coupled to a bottom surface 102 of the substrate 100 and may form a first array (e.g., an array of interconnects), and the interconnects 106 may be coupled to the bottom surface 102 of the substrate 100 and may form a second array (e.g., an array of interconnects), as further described herein. The interconnects 104, 106 may be coupled to off-package contacts of the substrate 100, and thus may be referred to as off-package interconnects. In some aspects, the interconnects 104 are a first type of interconnect (or have a first structure) that is different from a second type of interconnect (or a second structure) of the interconnects 106, the first array formed by the interconnects 104 is a different type of array than the second array formed by the interconnects 106, or both, as further described herein.

The substrate 100 includes a set of dielectric layers and a set of metal layers. The dielectric layers may include or correspond to polymer layers, such as fiber reinforced polymer layers, and the metal layers may include or correspond to foil layers, such as copper foil layers, as non-limiting examples. The metal layers are patterned and interconnected to define conductive paths of the substrate 100. For example, the metal layers may be patterned to form conductive paths to facilitate off-package connections from a die, or another on-package component, to a printed circuit board (PCB). Additionally, or alternatively, the metal layers may be patterned to facilitate on-package connections, such as die-to-die (D2D) connections or other connections, between multiple on-package components.

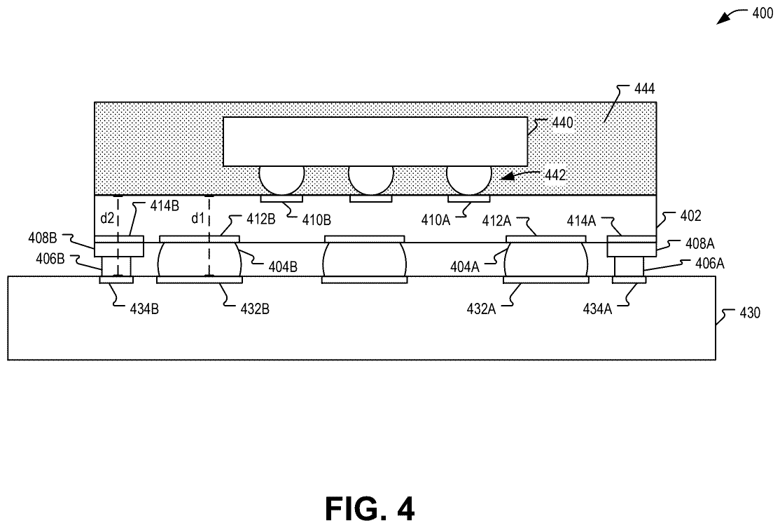

As illustrated in FIG. 1B, a metal layer may include (or be patterned to form) on-package contacts 110, and another metal layer may include (or be patterned to form) off-package contacts 112 (e.g., a first subset of off-package contacts) and off-package contacts 114 (e.g., a second subset of off-package contacts). Any of the conductive interconnects and contacts described herein can include, for example, microbumps, conductive pillars, conductive pads (e.g., for pad-to-pad bonding), or other similar chiplet-to-chiplet interconnect contacts used for 2.5D or three-dimensional (3D) chiplet stacking. Conductive paths between the various pads may facilitate the off-device connections, the on-device connections, or both. To illustrate, the off-package connections can be formed via conductive paths that extend between contacts on the bottom surface 102 (e.g., a first surface) of the substrate 100, such as the off-package contacts 112 or the off-package contacts 114, and contacts on a top surface 103 (e.g., a second surface) of the substrate 100, such as the on-package contacts 110 To further illustrate, the on-package connections can be formed via conductive paths that extend between multiple contacts on the top surface 103, such as between multiple of the on-package contacts 110 and one or more layers of the substrate 100. The on-package contacts 110 may be configured to be coupled to the one or more dies, and the off-package contacts 112, 114 may be configured to be coupled to a PCB as further described herein with reference to FIG. 4.

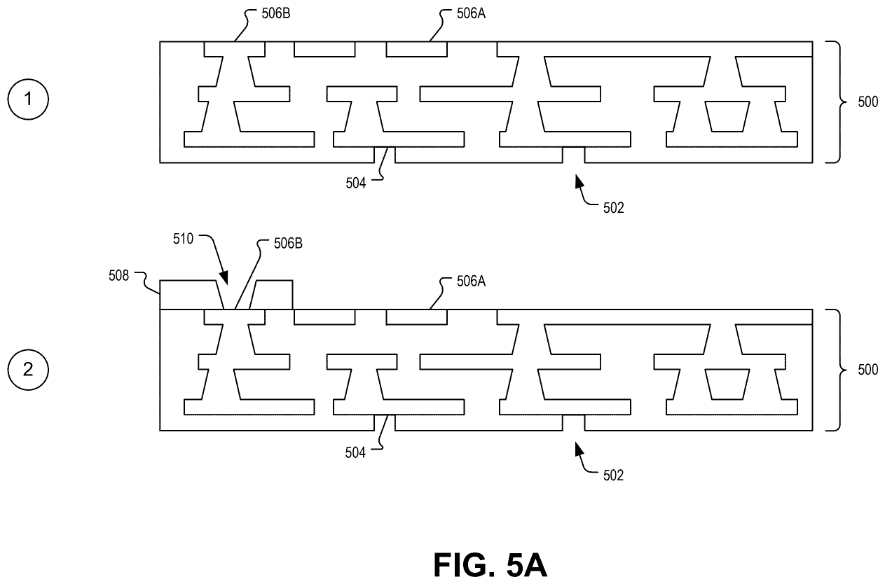

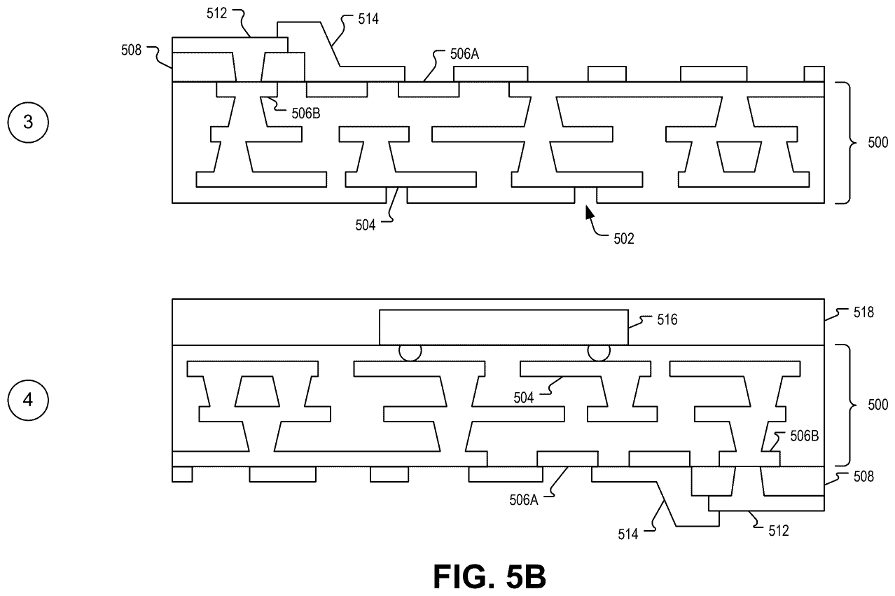

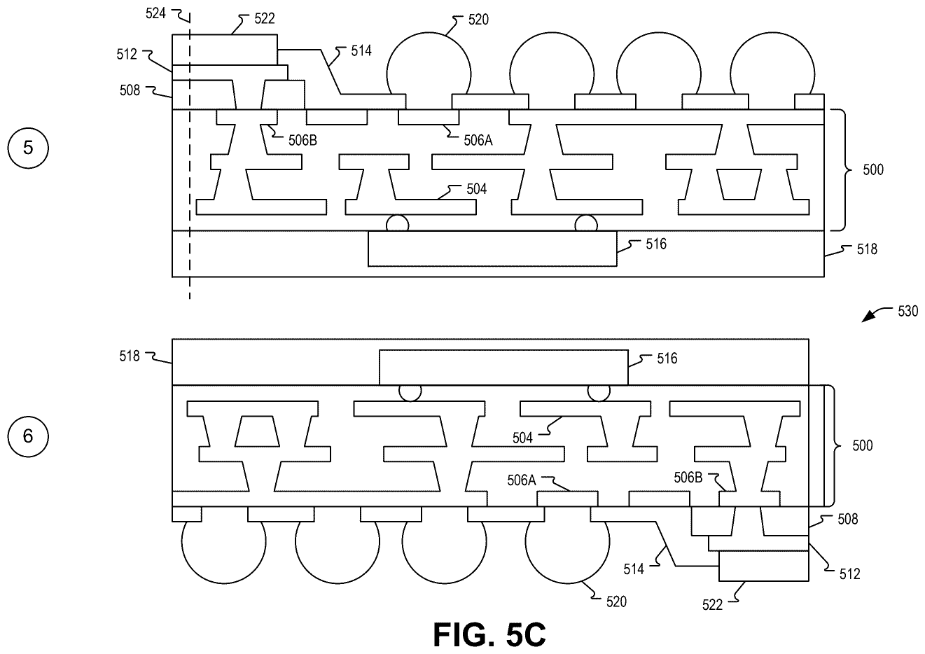

The substrate 100 also includes conductive structures 108 that are coupled to at least some off-package contacts. For example, the conductive structures 108 (e.g., a set of conductive structures) may be electrically coupled to the off-package contacts 114 (e.g., a subset of off-package contacts). In some implementations, the conductive structures 108 include copper pads that extend to the edges of the substrate 100. For example, the conductive structures 108 may be formed by depositing dielectric layer(s) on a region of the substrate 100 that includes the off-package contacts 114, forming one or more cavities that expose portion(s) of the off-package contacts 114, and depositing a conductive material (e.g., copper) on the dielectric layer(s) and within the cavities. In this example, the dielectric layers can include photo-imageable dielectric (PID) materials or solder resist (SR) materials. An example of formation of the conductive structures 108 is further described herein with reference to FIGS. 5A-C. In some other implementations, the conductive structures 108 include integrated metal pads, such as M3 integrated pads.

The various off-package contacts of the substrate 100 are coupled to respective interconnects to facilitate the above-described off-package connections. For example, the interconnects 104 (e.g., a first set of electrical interconnects) may be coupled to the off-package contacts 112 (e.g., a first subset of off-package contacts), and the interconnects 106 (e.g., a second set of electrical interconnects) may be coupled to the off-package contacts 114 (e.g., a second subset of off-package contacts). The interconnects 104 may be a different type of interconnect than the interconnects 106, such as by having a different shape or structure, being associated with different design rules, etc. In some aspects, the interconnects 104 include a set of solder balls and the interconnects 106 include a set of substantially planar solder structures or solder paste. For example, the interconnects 106 can be formed from conventional solder paste as small, substantially planar solder structures using paste print techniques.

As shown in the example of FIG. 1A, the interconnects 104 and the interconnects 106 form multiple types of arrays for being coupled to a PCB. For example, the interconnects 104 may form a ball grid array (BGA), and the interconnects 106 may form a land grid array (LGA). As compared to a BGA, which is an array of solder balls that are configured to be coupled to an off-package structure such as a PCB, the LGA is an array of solder structures that have a substantially flat surface for coupling to the off-package structure. To illustrate, the interconnects 104 may include solder balls that are coupled to the off-package contacts 112 in positions that form a first array and that comply with one or more BGA design rules or criteria. Additionally, the interconnects 106 may include planar solder structures that are coupled to the conductive structures 108 formed on the off-package contacts 114 in positions that form a second array. Although illustrated in FIG. 1A as including rectangular solder structures and t-shaped solder structures (e.g., located at the corners of the substrate 100), in other implementations, the interconnects 106 do not include the t-shaped solder structures. As used herein, an “array” refers to an ordered series or arrangement of elements and does not necessarily imply any particular configuration or spacing between elements. In some examples, an array (e.g., a BGA, an LGA, or both) includes elements that are disposed in a two-dimensional configuration that includes rows and columns, optionally with fixed spacing (in either or both dimensions) between elements. In other examples, the array does not include rows or columns, and spacing between elements in one or more dimensions may not be fixed.

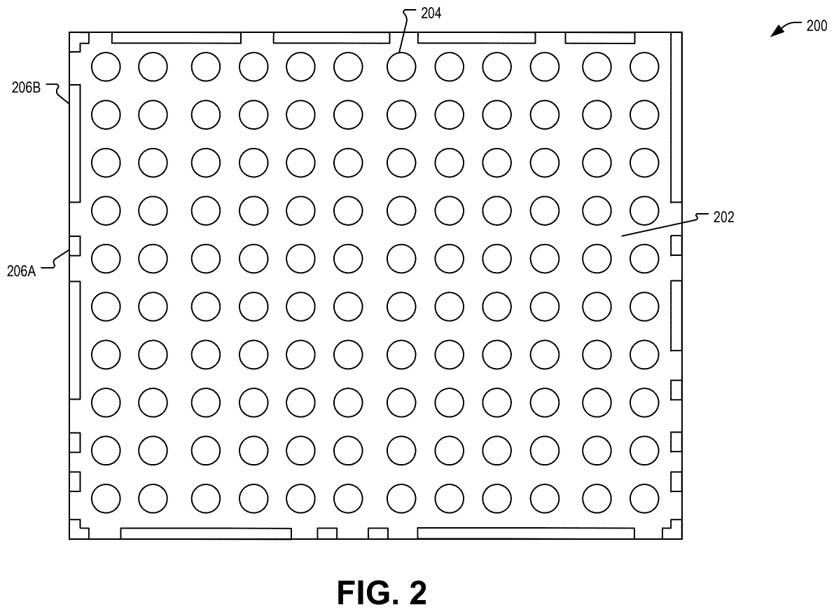

Although the example illustrated in FIG. 1A includes one hundred and twenty of the interconnects 104, arranged in ten rows each having twelve interconnects and twelve columns each having ten interconnects, in other examples, the interconnects 104 may include fewer than or more than one-hundred and twenty interconnects, fewer than ten or more than ten rows, fewer than twelve or more than twelve columns, or a combination thereof. Additionally, or alternatively, although the example illustrated in FIG. 1A includes forty-four of the interconnects 106, arranged in two rows each having thirteen interconnects and two columns each having eleven interconnects, in other examples, the interconnects 106 may include fewer than or more than forty-four interconnects, fewer than two or more than two rows, fewer than two or more than two columns, or a combination thereof. In some examples, many of the interconnects 106 have the same, or substantially similar, dimensions. For example, most of the interconnects 106 (e.g., other than those located at the corners of the substrate 100) may have a same width and a same length, and the t-shaped interconnects at the corners may have similar dimensions to each other. In other examples, one or more of the interconnects 106 may have different dimension(s) than others of the interconnects 106, as further described herein with reference to FIG. 2.

The interconnects 106 may be disposed along, or adjacent to, the outer edges of the substrate 100 (e.g., along the periphery of the substrate 100) such that the interconnects 106 that form the LGA surround the interconnects 104 that form the BGA. For example, the interconnects 104 (and the off-package contacts 112) may be disposed within a first region 120 (e.g., an “interior region”) of the bottom surface 102 of the substrate 100, and the interconnects 106 (and the off-package contacts 114) may be disposed within a second region 122 (e.g., a “peripheral region”) of the bottom surface 102 of the substrate 100. As illustrated in FIG. 1A, the second region 122 may surround the first region 120, such that the LGA surrounds the BGA. In some embodiments, at least a portion of the substrate 100 in the second region 122 includes more layers than in the first region 120. To illustrate, the substrate 100 in the first region 120 may include a first number of layers between the bottom surface 102 and the top surface 103, and at least a portion of the substrate 100 in the second region 122 may include a second number of layers between the bottom surface 102 and the top surface 103. The second number of layers is greater than the first number of layers such that one or more additional layers may be used to form the conductive structures 108, as further described herein with reference to FIGS. 5A-C.

As illustrated in FIG. 1A, the interconnects 104 and the off-package contacts 112 within the first region 120 are interior to and surrounded by the interconnects 106, the conductive structures 108, and the off-package contacts 114 within the second region 122. As such, the interconnects 104, or the off-package contacts 112, are disposed at least partially (e.g., in a particular direction) between two corresponding ones of the interconnects 106, or the off-package contacts 114, respectively, each of which are adjacent to or along different edges of the substrate 100. For example, the interconnect 104A or the interconnect 104B may be disposed (in a direction of the x-axis in FIG. 1A) at least partially between the interconnect 106A and the interconnect 106B. Similarly, the off-package contact 112A or the off-package contact 112B may be disposed (in a direction of the x-axis in FIG. 1B) at least partially between the off-package contact 114A and the off-package contact 114B. As another example, the interconnect 104A may be disposed (in a direction of the y-axis in FIG. 1A) at least partially between the interconnect 106C and the interconnect 106D.

Additionally, one or more of the interconnects 106, or the off-package contacts 114, may be disposed between an edge of the substrate 100 and one or more of the interconnects 104, or the off-package contacts 112, respectively. For example, the interconnect 106A may be disposed (in a direction of the x-axis in FIG. 1A) between the interconnect 104A and a first edge (e.g., a right edge) of the substrate 100. Similarly, the off-package contact 114A may be disposed (in a direction of the x-axis in FIG. 1B) between the off-package contact 112A and the first edge of the substrate 100. As another example, the interconnect 106B may be disposed (in a direction of the x-axis in FIG. 1A) between the interconnect 104B and a second edge (e.g., a left edge) of the substrate 100, and the off-package contact 114B may be disposed between the off-package contact 112B and the second edge. In some embodiments, each of the interconnects 104, or the off-package contacts 112, are disposed at least partially between a pair of the interconnects 106, or a pair of the off-package contacts 114, respectively, and each of the interconnects 106, or each of the off-package contacts 114, is disposed between an edge of the substrate 100 and one or more of the interconnects 104, or one or more of the off-package contacts 112, respectively. Thus, the interconnects 106, the conductive structures 108, and the off-package contacts 114 are disposed within the second region 122 that is outside of, and that surrounds, the first region 120 in which the interconnects 104 and the off-package contacts 112 are disposed. As such, the substrate 100 leverages area along the periphery that is not used in other packaged devices to include additional electrical interconnections, thereby increasing an interconnect density of the substrate 100 as compared to conventional package substrates.

The dimensions of the interconnects 106, and the spacing of the interconnects 106 with respect to the interconnects 104, may be set by design rules or other goals associated with the substrate 100 (or the packaged device for which the substrate 100 is the package substrate). In some examples, a width (e.g., in the direction of the x-axis in FIGS. 1A and 1B) is approximately 190 microns (also referred to as micrometers (μm)), but in other examples the width can be smaller or larger than 190 μm. In some embodiments, the interconnects 106 may use a non-solder mask defined (NSMD) pad (e.g., the conductive structures 108), such that the solder of the interconnects 106 can be larger (e.g., in one or more dimensions) than the copper pad (e.g., the conductive structurse 108) beneath the solder. Such formation technique may be preferred due to simpler design and larger exposed copper area for coupling to the interconnects 106. Additionally, or alternatively, the spacing between the interconnects 104 may be defined by substrate manufacturing rules or regular assembly rules, and the spacing between the interconnects 106, or between one of the interconnects 106 and one of the interconnects 104, can be the same spacing or a different spacing. As an example, a distance d1 between the interconnect 104A and the interconnects 104C may be 200 μm, and a distance d2 between the interconnect 104A and the interconnect 106A may also be 200 μm. In other examples, the distance d2 between the interconnects 104A, 106A may be smaller or larger than the distance d1 between the interconnects 104A, 104C.

A combined thickness of the interconnects 106 and the conductive structures 108 may be substantially the same as a thickness of the interconnects 104 to enable the interconnects 106 and the interconnects 104 to be coupled to a substantially flat surface, such as a surface of a PCB. To illustrate, a first thickness t1 of the interconnect 104B with respect to a first axis that is geometrically normal to the substrate 100 and that extends through the 104B interconnect (e.g., an axis parallel to the z-axis) is greater than a second thickness t2 of the interconnect 106B with respect to a second axis that is geometrically normal to the substrate and that extends through the interconnect 106B (e.g., an axis parallel to the z-axis). However, a combined thickness t3 of the interconnect 106B and the conductive structure 108B is substantially the same as the first thickness t1 of the interconnect 104B. Extruding an edge pad from the substrate 100 to form the conductive structure 108B enables a small standoff for solder paste to form the interconnect 106B, thereby providing more structural support than applying solder having the same thickness as the interconnect 104B (e.g., a conventional BGA thickness).

The interconnects 106 may be coupled to one or more signal sources on a PCB to provide additional interconnections to the substrate 100 as compared to conventional package substrates. In some implementations, the interconnects 106 are configured to be coupled to a common ground via the substrate 100 and the PCB (as further described with reference to FIG. 4). Coupling the interconnects 106 to ground may free up the interconnects 104 that would otherwise have been coupled to ground to be used for additional power or signal interconnections, which can increase the I/O or signal interconnect count of the substrate 100 compared to conventional substrates. Alternatively, the substrate 100 may have a reduced size compared to conventional substrates that have the same I/O density by omitting some of the interconnects 104 that would otherwise have been coupled to ground. Additionally, or alternatively, the interconnects 106 may be configured to be coupled to a common source voltage via the substrate 100 and the PCB. Similar to as described with reference to providing additional ground interconnections, providing additional power (Vdd or Vss) interconnections can increase the number of the interconnects 104 that provide signal interconnections, thereby increasing interconnect density of the substrate 100, or reduce the size of the substrate 100 by omitting the interconnects 104 that would otherwise provide power interconnections. Additionally, or alternatively, the interconnects 106 may be configured to provide one or more signal pathways between the substrate 100 and the PCB. Providing additional signal pathways through the interconnects 106 may increase the signal interconnect density of the substrate 100 or reduce the size of the substrate 100 (e.g., by enabling omission of some of the interconnects 104 that would otherwise provide the corresponding signal pathways). However, tighter design rules associated with signal pathway interconnections may make such design more challenging than using the interconnects 106 to provide power or ground interconnections.

It should be understood that the substrate 100 may include additional components or circuitry, other components or circuitry, fewer components or circuitry, or a combination thereof, to support the functionality described herein. As non-limiting examples, the substrate 100 may include additional or fewer metal layers, additional or fewer dielectric layers, additional or fewer of the interconnects 104, additional or fewer of the interconnects 106, other interconnects, additional or fewer pads, or a combination thereof, to support the functionality and technical advantages disclosed herein.

The substrate 100 thus provides an increased off-package connection density by leveraging space on a package substrate that goes unused in other package substrate designs to provide additional connections through the interconnects 106. As a result, the substrate 100 can provide an increased number of off-package connections (e.g., due to the interconnects 104 and the interconnects 106) as compared to another package substrate having the same size, or the substrate 100 can have a reduced size as compared to another package substrate that provides the same number of off-package connections as the substrate 100. An additional benefit of the substrate 100 is that the interconnects 106 (e.g., the subset of off-package interconnects that form the LGA in the second region 122) provide additional connections between the substrate 100 and a PCB coupled to the bottom of the substrate 100, which can reduce or prevent warpage along the edges of the substrate 100. For example, a physical coupling of the interconnects 106 to a lower substrate or PCB provides additional physical joints that reduce the area of the substrate 100 that are not nearby a physical joint, and thus free to warp or bend over time in conventional substrates.

FIG. 2 illustrates a bottom view of another exemplary substrate 200 that includes multiple arrays of off-package interconnects. In some implementations, the substrate 200 may include or correspond to the substrate 100 of FIGS. 1A and 1B. In the example illustrated in FIG. 2, the substrate 200 includes interconnects 204 (e.g., a first subset of interconnects) and interconnects 206 (e.g., a second set of interconnects) that are each coupled to a bottom surface 202 of the substrate 200. The interconnects 204 may be disposed within an interior region of the substrate 200 and may include solder balls that form a BGA. For example, the interconnects 204 may include or correspond to the interconnects 104 of FIGS. 1A and 1B.

The interconnects 206 may be disposed within a peripheral region of the substrate 200 (e.g., along or adjacent to one or more edges of the substrate 200) and may include solder paste or other substantially planar solder structures that form an LGA. Unlike the interconnects 106 of FIGS. 1A and 1B, the interconnects 206 of FIG. 2 may include interconnects having different sizes (e.g., at least one different dimension). For example, the interconnect 206A may have a smaller rectangular or square shape and may have similar width and length as compared to the interconnects 106 of FIGS. 1A and 1B. The interconnect 206B may have the same width as the interconnect 206A, however, the length of the interconnect 206B may be longer than the length of the interconnect 206A. In some embodiments, the interconnects 206 have lengths, or other dimensions, that are selected from one of a preset group of acceptable values. Alternatively, some or all of the interconnects 206 may have individual lengths, or other dimensions, that are different from others of the interconnects 206. As such, in some embodiments, a number of the interconnects 206 in different rows or in different columns may be different. The length, or other dimension, of the interconnects 206 may be selected during a design process to achieve one or more goals associated with the interconnects 206, the signaling provided by the interconnects 206, one or more design rules, one or more assembly rules, other criteria, or a combination thereof. As an example, the interconnect 206B, and optionally others of the interconnects 206 that are configured to be coupled to a common power source, may have longer pad sizes to provide increased copper volume in the power rails that can reduce direct current resistance (DCR). Additionally, or alternatively, longer lengths of some of the interconnects 206 can improve the strength of the mechanical joint that is formed by physically coupling the interconnects 206 to another structure, such as a PCB, thereby further reducing warping of the substrate 200.

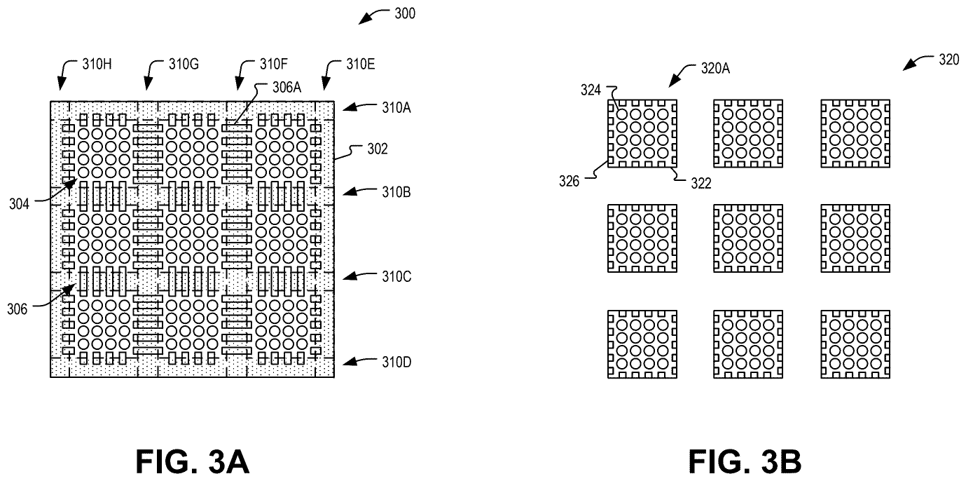

FIGS. 3A and 3B illustrate stages during panel level fabrication of an exemplary substrate that includes multiple arrays of off-package interconnects. In some implementations, the panel level fabrication of FIGS. 3A and 3B may be used to provide (e.g., during fabrication of) the substrate 100 of FIGS. 1A and 1B or the substrate 200 of FIG. 2. In the following description, reference is made to various illustrative Stages of the panel level fabrication (e.g., one or more operations performed at a panel level of a fabrication process), although such operations could also be performed at the wafer level or the strip level. Each of the various stages of the panel level fabrication illustrated in FIGS. 3A-B shows multiple substrates being formed concurrently. In other implementations, a single substrate can be formed, or one or more operations described with reference to the panel level fabrication of FIGS. 3A and 3B can be performed after singulation (e.g., as one or more unit level operations performed during a fabrication process).

Stage 1 of FIG. 3A illustrates a state after sets of interconnect structures 304 and sets of interconnect structures 306 are coupled to a bottom surface 302 of a substrate panel 300. For example, each portion of the substrate panel 300 that is to be used to form an individual substrate may have disposed, on the bottom surface 302, a corresponding set of interconnect structures 304 and a corresponding set of interconnect structures 306 (which may partially overlap with an adjacent portion). Each set of the interconnect structures 304 may form a BGA, and each set of the interconnect structures 306 may form an LGA, as described above with reference to FIGS. 1A and 1B. During or after Stage 1, multiple regions of the substrate panel 300 may be designated as sawing streets 310 that divide the various portions of the substrate panel 300 into individual units to be formed after singulation. For example, the substrate panel 300 may be cut along the sawing streets 310 to separate the illustrated substrate panel 300 into nine individual units (e.g., individual substrates) that are then further processed by one or more unit level operations of the fabrication process. Thus, the sawing streets 310 may represent area of the substrate panel 300 that will be destroyed or otherwise discarded during the fabrication process.

The interconnect structures 306 may overlap one or more of the sawing streets 310, as illustrated in FIG. 3A. As such, at least some of the interconnect structures 306 in FIG. 3A may be cut to form pairs of interconnect structures 306, with one interconnect structure 306 of the pair being included in one unit and the other interconnect structure 306 of the pair being included in an adjacent unit. To illustrate, a first portion of the interconnect structure 306A is included in an upper-right unit, a second portion of the interconnect structure 306A is included in an upper-middle unit, and a third portion (e.g., between the first portion and the second portion) overlaps the sawing street 310F. During cutting, the third portion may be cut away and discarded, resulting in the first unit including a first interconnect formed from the first portion of the interconnect structure 306A and the second unit including a second interconnect formed from the second portion of the interconnect structure 306A. In this manner, many of the interconnect structures 306 illustrated in FIG. 3A may, at Stage 1, extend across a respective one of the sawing streets 310 and, during cutting, be cut apart to form respective interconnect structures 306 of two adjacent units of the substrate panel 300.

Although the interconnect structures 306 (e.g., planar solder structures or solder paste) are described as extending across the sawing streets 310 and having portions within multiple units, this is an illustrative example. In other embodiments, conductive structures (e.g., extruded copper pads, which may include or correspond to the conductive structures 108 of FIGS. 1A and 1B) may extend across the sawing streets 310 and have portions in multiple units of the substrate panel 300. In these embodiments, the interconnect structures 306 (e.g., the planar solder structures or the solder paste) may be formed only on the portions of the conductive structures that are within the various units of the substrate panel 300 (e.g., that are not over the sawing streets 310). However, forming the interconnect structures 306 that extend over the sawing streets 310 may be more efficient due to the use of panel level operations.

Stage 2 of FIG. 3B illustrates a state after the substrate panel 300 is cut along the sawing streets 310 to form multiple substrates 320 (e.g., individual units). For example, the substrate panel 300 may be cut along the sawing street 310A, 310B, 310G, and 310H to form the substrate 320A. Cutting along one of the sawing streets 310 between a first unit that is to include one or more dies and a second unit that is to include one or more other dies may include cutting at least a portion of the substrate panel 300, at least a portion of one or more dielectric layers, at least a portion of one or more conductive structures, and at least a portion of a mold compound, as further described herein with reference to FIGS. 5A-5C. Each of the substrates 320 may include corresponding interconnects forming a BGA and corresponding interconnects forming an LGA. For example, the substrate 320A includes interconnects 324 and interconnects 326 coupled to a bottom surface 322 of the substrate 320A. The interconnects 324 form a BGA and the interconnects 326 form an LGA that surrounds the BGA. At least some of the interconnects 326 are formed by cutting larger interconnect structures between Stage 1 and Stage 2. For example, cutting along the sawing street 310G may form some of the interconnects 326 and some interconnects in an upper-middle one of the substrates 320 from the interconnect structures 306 illustrated in FIG. 3A as extending between the upper-left portion and the upper-middle portion of the substrate panel 300. As another example, cutting along the sawing street 310B may form some of the interconnects 326 and some interconnects in a middle-left one of the substrates 320 from the interconnect structures 306 illustrated in FIG. 3A as extending between the upper-left portion and the middle-left portion of the substrate panel 300.

### Exemplary Device Including a Substrate that Includes Multiple Arrays of Off-Package Package Interconnects

FIG. 4 illustrates a cross-sectional profile view of a particular implementation of a device 400 that includes an exemplary substrate 402 that includes multiple arrays of off-package interconnects. In some implementations, the substrate 402 includes or corresponds to the substrate 100 of FIGS. 1A and 1B, the substrate 200 of FIG. 2, or the substrate 320A of FIG. 3B. In the example shown in FIG. 4, the device 400 includes a PCB 430, one or more dies 440 (referred to herein collectively as the “die 440”), and the substrate 402 disposed between the die 440 and the PCB 430. The substrate 402 may be coupled to the PCB 430 and to the die 440, and the die 440 may be coupled to the PCB 430 via the substrate 402. For example, the substrate 402 may be coupled to the PCB 430 using interconnects 404 and interconnects 406, and the die 440 may be coupled to the substrate 402 using interconnects 442, as further described herein. Although referred to as a PCB, in other implementations, the PCB 430 may be a different type of substrate to which the substrate 402 is electrically and physically coupled. The device 400 may also include a mold compound 444 that is deposited over and at least partially surrounding the die 440 (and the interconnects 442). The substrate 402, the die 440, and the mold compound 444 may be referred to as a packaged IC device.

The die 440 can include integrated circuitry, such as a plurality of transistors and/or other circuit elements arranged and interconnected to form logic cells, memory cells, etc. Components of the integrated circuitry can be formed in and/or over a semiconductor substrate. Different implementations can use different types of transistors, such as a field effect transistor (FET), planar FET, finFET, a gate all around FET, or mixtures of transistor types. In some implementations, a front end-of-line (FEOL) process may be used to fabricate the integrated circuitry in and/or over the semiconductor substrate.

The die 440 may include or correspond to particular IC devices that can be arranged and interconnected as a three-dimensional (3D) IC device or a 2.5D IC device. In some implementations, the die 440 includes one or more microcontrollers, application specific integrated circuits (ASICs), field programmable gate arrays (FPGAs), central processing units (CPUs) having one or more processing cores, processing systems, system on chip (SoC), or other circuitry and logic configured to facilitate the operations of the die 440. Additionally, or alternatively, the die 440 may include or be operated as a memory, such as a static random-access memory (SRAM), a dynamic random-access memory (DRAM), flash memory, read-only memory (ROM), programmable read-only memory (PROM), erasable programmable read-only memory (EPROM), electrically erasable programmable read-only memory (EEPROM), a solid-state storage device (SSD), or a combination thereof.

Although the die 440 is illustrated in FIG. 4 as directly coupled to the substrate 402 (e.g., using the interconnects 442, which may include solder bumps), in some implementations, the die 440 is electrically connected to, or integrated with, respective substrates. For example, the die 440 (and optionally one or more additional dies) can include a packaged IC device that, together with the die 440, is coupled to the substrate 402 to form a package-on-package device. Further, although FIG. 4 illustrates a single die 440, in other examples, the device 400 can include more than one die 440.

The substrate 402 includes a set of dielectric layers and a set of metal layers, similar as to described above with reference to the substrate 100 of FIGS. 1A and 1B. The dielectric layers may include or correspond to polymer layers, such as fiber reinforced polymer layers, and the metal layers may include or correspond to foil layers, such as copper foil layers, as non-limiting examples. The metal layers are patterned and interconnected to define conductive paths of the substrate. For example, the metal layers may be patterned to form conductive paths to facilitate off-package connections from the PCB 430 to the die 440. Additionally, or alternatively, the metal layers may be patterned to facilitate on-package connections, such as D2D connections or other connections, between multiple on-package components, such as the die 440 and other components (not shown).

In the example shown in FIG. 4, the substrate 402 includes on-package contacts 410 coupled to the die 440 and off-package contacts 412, 414 coupled to the PCB 430. The on-package contacts 410 may be disposed on a top surface of the substrate 402 and may include or correspond to the on-package contacts 110 of FIGS. 1A and 1B. The off-package contacts 412, 414 may be disposed on a bottom surface of the substrate 402 and may include or correspond to the off-package contacts 112, 114 of FIGS. 1A and 1B, respectively. The device 400 also includes interconnects 404 (e.g., a first set of electrical interconnects) and interconnects 406 (e.g., a second set of electrical interconnects). The interconnects 404 are coupled to the off-package contacts 412 and to off-board contacts 432 of the PCB 430. The interconnects 406 are coupled to the off-package contacts 414 and to off-board contacts 434 of the PCB 430. In some aspects, the interconnects 406 are coupled to the off-package contacts 414 through conductive structures 408, such as extruded copper (or other metal) pads. The interconnects 404 may include solder balls and form a BGA, and the interconnects 406 (and the conductive structures 408) may include solder paste or substantially planar solder structures that form an LGA and that surround the BGA (e.g., that are disposed along or adjacent to edge(s) of the substrate 402). For example, the interconnects 404, the interconnects 406, and the conductive structures 408 include or correspond to the interconnects 104, the interconnects 106, and the conductive structures 108 of FIGS. 1A and 1B, respectively.

The thickness of the interconnects 406 may be substantially the same as the combined thickness of the interconnects 406 and the conductive structures 408, such that the substrate 402 can be coupled to a substantially planar surface of the PCB 430. For example, a first distance d1 between a first point on a first surface (e.g., the top surface that includes the on-package contacts 410) of the substrate 402 and a corresponding first point on a surface of the PCB 430 is substantially the same as a second distance d2 between a second point on the first surface of the substrate 402 and a corresponding second point on the surface of the PCB 430. As illustrated in FIG. 4, the interconnect 404B (e.g., a first electrical interconnect of the first set of electrical interconnects) is disposed between the first point on the first surface of the substrate 402 and the corresponding first point on the surface of the PCB 430. In this example, the interconnect 406B (e.g., a second electrical interconnect of the second set of electrical interconnects) is disposed between the second point on the first surface of the substrate 402 and the corresponding second point on the surface of the PCB 430.

The interconnects 404 (or a subset thereof) may be configured to provide a first type of interconnections between the substrate 402 (or the die 440) and the PCB 430, and the interconnects 406 (or a subset thereof) may be configured to provide a second type of interconnections between the substrate 402 (or the die 440) and the PCB 430. The types of interconnections may include a common ground, a common power source, or signal paths, as described above with reference to FIGS. 1A and 1B. As an example, the interconnects 404 may provide one or more signal pathways between the substrate 402 (or the die 440) and the PCB 430, and the interconnects 406 may be coupled to a common ground or a common source voltage via the substrate 402 and the PCB 430. Such a configuration may have less stringent design rules than providing signal pathways through the interconnects 406, while still either increasing the interconnect density of the substrate 402 (as at least some of the interconnects 404 that would otherwise have been coupled to common ground and the common source voltage can instead be used to provide signal paths) or reducing the size of the substrate 402 (e.g., due to the portion of the interconnects 404 that would have been coupled to common ground and the common source voltage being omitted).

In a particular implementation, the device 400 includes one or more dies (e.g., the die 440) and a substrate (e.g., the substrate 402). The substrate includes on-package contacts (e.g., the on-package contacts 410) coupled to the one or more dies and off-package contacts (e.g., the off-package contacts 412, 414) configured to be coupled to a PCB (e.g., the PCB 430). The device also includes a first set of electrical interconnects (e.g., the interconnects 404) electrically coupled to a first subset of the off-package contacts (e.g., the off-package contacts 412) and that form a BGA. The device also includes a second set of electrical interconnects (e.g., the interconnects 406) electrically coupled to a second subset of the off-package contacts (e.g., the off-package contacts 414) and that form an LGA.

In another particular implementation, the device 400 includes one or more dies (e.g., the die 440), a PCB (e.g., the PCB 430), and a substrate (e.g., the substrate 402) disposed between the one or more dies and the PCB. The substrate includes on-package contacts (e.g., the on-package contacts 410) coupled to the one or more dies and off-package contacts (e.g., the off-package contacts 412, 414) coupled to the PCB. The device also includes a first set of electrical interconnects (e.g., the interconnects 404) electrically coupled to a first subset of the off-package contacts (e.g., the off-package contacts 412) and to the PCB and that form a BGA. The device also includes a second set of electrical interconnects (e.g., the interconnects 406) electrically coupled to a second subset of the off-package contacts (e.g., the off-package contacts 414) and to the PCB and that form an LGA.

It should be understood that the device 400 may include additional components or circuitry, other components or circuitry, fewer components or circuitry, or a combination thereof, to support the functionality described herein. As non-limiting examples, the device 400 may include additional or fewer IC devices, additional or fewer layers, additional or fewer dies, additional or fewer packages, additional or fewer interconnects, additional structures, other components or circuitry, different components or circuitry, or a combination thereof, to support the functionality and technical advantages disclosed herein.

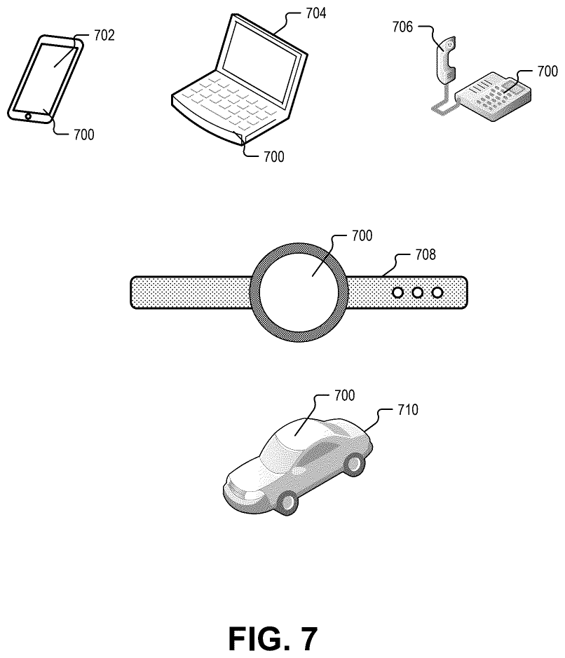

In some implementations, the device 400 can be integrated in a smartphone, a tablet computer, a fixed location terminal device, an automobile, a wearable electronic device, a laptop computer, or some combination thereof, as described in more detail below with reference to FIG. 7. As described with reference to FIG. 4, the device 400 includes the substrate 402 that provides an increased off-package connection density by leveraging space on a package substrate that goes unused in other package substrate designs to provide additional connections through the interconnects 406. As a result, the substrate 402 can provide an increased number of off-package connections (e.g., due to the interconnects 404 and the interconnects 406) as compared to another package substrate having the same size, or the substrate 402 can have a reduced size as compared to another package substrate that provides the same number of off-package connections as the substrate 402. Accordingly, the device 400 can support system on chip device(s) (e.g., the die 440) that have advanced functionality associated with an increased number of connections, as compared to other devices that include a packaged integrated device. An additional benefit of the substrate 402 is that the interconnects 406 (e.g., the subset of off-package interconnects that form the LGA in a peripheral region of the substrate 402) provide additional connections between the substrate 402 and the PCB 430, which can reduce or prevent warpage along the edges of the substrate 402 during the lifetime of the device 400. For example, the coupling of the interconnects 406 to the PCB 430 provide stronger joints that reduce the ability of the substrate 402 to warp due to unsupported areas near the edges.

While FIG. 4 illustrates an example device that includes a single package disposed on the PCB 430, in other examples, one or more additional integrated devices, packages, or some combination thereof can be present in a stacked integrated circuit without departing from the scope of the subject disclosure. Further, the substrate 402 of FIG. 4 can be integrated with or included within a wide variety of other devices. For example, a device that includes one or more of the substrate 402 and the interconnects 404, 406 disclosed herein can include components such as a power management integrated circuit (PMIC), an application processor, a modem, a radio frequency (RF) device, a passive device, a filter, a capacitor, an inductor, a transmitter, a receiver, a gallium arsenide (GaAs) based integrated device, a surface acoustic wave (SAW) filter, a bulk acoustic wave (BAW) filter, a light emitting diode (LED) integrated device, a silicon (Si) based integrated device, a silicon carbide (SiC) based integrated device, a memory, power management processor, and/or combinations thereof. In such devices, the substrate 402 can operate as a package substrate for any of these components (or a combination of these components).

### Exemplary Sequence for Fabricating a Device Including a Substrate that Includes Multiple Arrays of Off-Package Interconnects

In some implementations, fabricating a device including a substrate that includes multiple off-package interconnects (e.g., the device 400) includes several processes. FIGS. 5A-C illustrate an exemplary sequence for fabricating or providing a device that includes a substrate including multiple off-package interconnects, as described with reference to any of FIGS. 1A-4. In some implementations, the sequence of FIGS. 5A-C may be used to provide (e.g., during fabrication of) one or more of the substrate 100 of FIGS. 1A and 1B, the substrate 200 of FIG. 2, the substrates 320 of FIGS. 3A and 3B, or the device 400 of FIG. 4.

It should be noted that the sequence of FIGS. 5A-C may combine one or more stages in order to simplify and/or clarify the sequence for providing or fabricating an integrated device. In some implementations, the order of the processes may be changed or modified. In some implementations, one or more of the processes may be replaced or substituted without departing from the scope of the disclosure. In the following description, reference is made to various illustrative Stages of the sequence, which are numbered (using circled numbers) in FIGS. 5A-C. Each of the various stages of the sequence illustrated in FIGS. 5A-C shows a single integrated device being formed, however, such depiction is for ease of illustration and not an indication that only a single integrated device is formed at a time. Instead, the sequence illustrated in FIGS. 5A-C may be performed using one or more panel level operations. In other implementations, a plurality of integrated devices can be formed concurrently (e.g., using wafer level or strip level operations), or a single integrated device can be formed (e.g., using unit level operations).

Stage 1 of FIG. 5A illustrates a state after one or more layers of a substrate 500 are formed or provided. For example, as part of Stage 1, metal layers and dielectric layers may be formed in a layer stack, up to a layer associated with BGA contacts, to form the substrate 500. The metal layer(s) can be formed by application of a metal foil that is subsequently patterned to form metal lines. Patterning of the metal foil can be performed using subtractive processes, such as etching, laser cutting, etc. The dielectric layer(s) can be formed from a reinforced polymer material. For example, a pre-preg material including reinforcing fibers and a polymer (e.g., an epoxy resin) can be applied, or a core layer can be procured with unpatterned metal layers laminated on one side or both sides. Conductive vias can be formed through the dielectric layer(s) to interconnect portions of the metal layer(s) to form conductive paths through the substrate 500. For example, laser or mechanical drilling can be used to form openings in the dielectric layer(s) between the metal layers, and metal can be deposited in the openings to form the conductive vias. Additionally, or alternatively, openings 502 may be formed in a first surface (e.g., a bottom surface in the orientation illustrated in FIG. 5A) of the substrate 500 to expose on-package contacts 504 and, if needed, to expose off-package contacts 506, including one or more off-package contacts 506A configured to form a BGA and disposed within a first region of the substrate 500, as well as to expose one or more off-package contacts 506B configured to form an LGA and disposed within a second region of the substrate 500.

Stage 2 illustrates a state after formation of one or more additional dielectric layers 508 on the second region (e.g., a peripheral region) of the substrate 500 and formation of cavities 510 to expose the off-package contacts 506B. The cavities 510 can be formed using laser drilling, mechanical drilling, or similar operations. In some implementations, one or more of the cavities 510 can be formed in multiple steps. For example, the additional dielectric layers 508 can include multiple layers, in which case, openings (e.g., cavities) can be formed in one dielectric layer before a next dielectric layer is applied. In some examples, the additional dielectric layers 508 include one or more photo-imageable dielectric materials (PIDs). Alternatively, the additional dielectric layers 508 may include solder resist (SR) materials or other types of dielectric materials. Using PIDs for the additional dielectric layers 508 may reduce cost and complexity of forming the additional dielectric layers 508. Although FIG. 5A illustrates a single set of additional dielectric layers 508 and a single cavity 510 that exposes a single off-package contact 506B, additional dielectric layers may be formed along or adjacent to other edges of the substrate 500, with additional cavities formed within to expose other off-package contacts 506B, in order to provide an arrangement as shown in FIGS. 1A and 1B.

Although not shown in FIG. 5A, if the off-package contacts 506A, which are disposed in a first region (e.g., an interior region) of the substrate 500 are covered with dielectric or other materials after Stage 1, then Stage 2 also includes forming cavities to expose the off-package contacts 506A. As described further below, the first region surrounds the second region. Additionally, the first region (which may include or correspond to the first region 120 of FIG. 1A) has a first number of layers (e.g., a number of layers included in the substrate 500 after Stage 1), and the second region (e.g., a peripheral region that may include or correspond to the second region 122 of FIG. 1A) has a second number of layers (e.g., the number of layers included in the substrate 500 combined with the number of layers included in the additional dielectric layers 508) that is greater than the first number.

Stage 3 of FIG. 5B illustrates a state after forming a set of conductive structures 512 extending from the off-package contacts 506, and a dielectric material 514 may be deposited on at least a portion of the conductive structures 512 and the additional dielectric layers 508. For example, as part of Stage 3, metal deposition operations, such as plating, can be used to deposit metal (or other conductive material) on the additional dielectric layers 508 and in the cavities 510 to form the conductive structures 512 electrically coupled to the off-package contacts 506B. As a particular example, the conductive structures 512 may be formed using substrate copper plating and the dielectric material 514 may include SR material as part of an eSAP process to extrude package-edge copper pads. Alternatively, the conductive structures 512 may be formed from M3 integrated pads.

Stage 4 illustrates a state after a die 516 is attached to the substrate 500 and a mold compound 518 is deposited on and at least partially surrounding the die 516 and a surface of the substrate 500. For example, as part of Stage 4, the die 516 can be attached to the on-package contacts 504. The die 516 may be attached using surface mount technology (SMT) or using one or more interconnects between the die 516 and the substrate 500. The mold compound may be deposited on the die 516 and a top surface of the substrate 500 after the die 516 is attached to the substrate 500. It is noted that the substrate 500 is rotated 180° at Stage 4 as compared to Stage 3.

Stage 5 of FIG. 5C illustrates a state after interconnects 520 are coupled to the substrate 500 and form a BGA, and after interconnects 522 are coupled to the substrate 500 and form an LGA. For example, as part of Stage 5, the interconnects 520 may be coupled to the off-package contacts 506A and the interconnects 522 may be coupled to the conductive structures 512. It is noted that the substrate 500 is rotated 180° at Stage 5 as compared to Stage 4. Electrically coupling the interconnects 520 to the off-package contacts 506A may include attaching solder balls to the off-package contacts 506A to form the BGA, as described above with reference to the interconnects 104 of FIGS. 1A and 1B. Electrically coupling the interconnects 522 to the conductive structures 512 (that are electrically coupled to the off-package contacts 506B) may include depositing (e.g., printing) solder paste on the conductive structures 512 until a combined thickness of the conductive structures 512 and the interconnects 522 is substantially the same as the interconnects 520 (e.g., the solder balls) to form the LGA, as described above with reference to the interconnects 106 of FIGS. 1A and 1B. Alternatively, the interconnects 522 may be formed using smaller solder balls, such as paste print or micro-balls, on the conductive structures 512 (e.g., the extruded metal pads).

Stage 6 illustrates a state after cutting the substrate 500 and additional layer(s) along one or more sawing streets during singulation to generate multiple packages. For example, as part of Stage 6, at least a portion of the substrate 500, at least a portion of the additional dielectric layers 508, at least a portion of the conductive structures 512, at least a portion of the mold compound 518, and optionally, at least a portion of the interconnects 522, are cut along one or more sawing streets 524 that is identified in the illustration after Stage 5 as the area including and to the left of the dashed line. Additional details of cutting a substrate panel along one or more sawing streets are described above, with reference to FIGS. 3A and 3B. It is noted that the substrate 500 is rotated 180° at Stage 6 as compared to Stage 5.

Cutting along the one or more sawing streets 524 forms multiple devices from a single substrate panel, including a device 530 that includes the die 516. As such, forming the conductive structures 512, attaching the interconnects 520, 522, and cutting along the one or more sawing streets 524 may be performed at the panel level of a fabrication process to more efficiently form multiple packaged devices that have cleaner edges than extruding the conductive structures 512, applying the solder to form the interconnects 520, 522, and cutting each packaged device at the strip level or the unit level.

Formation of the device 530 (e.g., a packaged semiconductor device) is complete after Stage 6. For example, the device 530 includes the substrate 500 that includes multiple arrays of off-package interconnects (e.g., the interconnects 520 that form a BGA and the interconnects 522 that form an LGA). In some implementations, the device 530 includes or corresponds to the device 400 of FIG. 4. Additionally, or alternatively, in some implementations, the substrate 500 can include or correspond to the substrate 100 of FIGS. 1A and 1B, the substrate 200 of FIG. 2, the substrate 320A of FIG. 3B, or the substrate 402 of FIG. 4. Although certain Stages are illustrated in FIGS. 5A-C in forming the device 530, other processes can be included in the fabrication of the device 530 without departing from the scope of the subject disclosure. For example, fabricating the device 530 can include performing one or more panel level operations described above at the unit level. As another example, although the attachment of the die 516 and the deposition of the mold compound 518 are shown before the attachment of the interconnects 520, 522, in some other implementations, the interconnects 520, 522 may be coupled to the substrate 500 prior to the attachment of the die 516 and the deposition of the mold compound 518.

### Exemplary Flow Diagram of a Method for Fabricating a Device Including a Substrate that Includes Multiple Arrays of Off-Package Interconnects

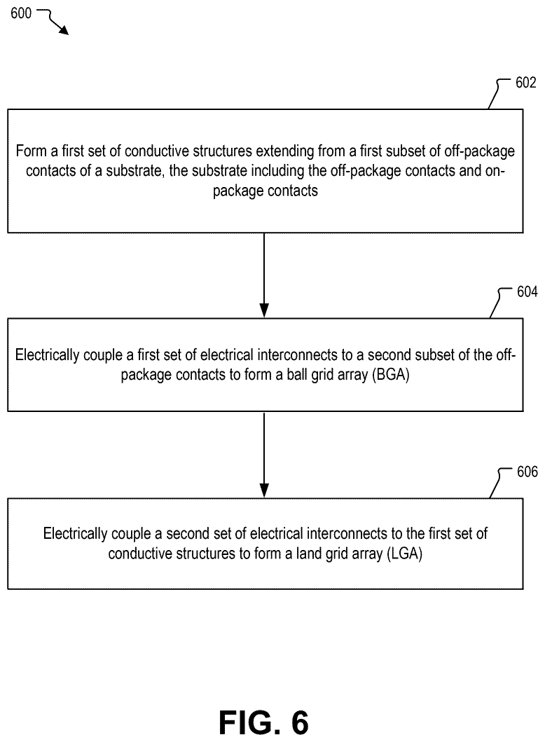

In some implementations, fabricating a device including a substrate that includes multiple arrays of off-package interconnects includes several processes. FIG. 6 illustrates an exemplary flow diagram of a method 600 of fabricating an illustrative device that includes a substrate including multiple arrays of off-package interconnects. In a particular aspect, one or more operations of the method 600 are performed by one or more processors of a fabrication system. In some implementations, operations of the method 600 may be stored as instructions by a non-transitory computer-readable storage medium, and the instructions may be executable by at least one processor to cause the at least one processor to initiate, perform, or control operations of the method 600. In some implementations, the method 600 of FIG. 6 may be used to provide or fabricate any of the substrate 100 of FIGS. 1A and 1B, the substrate 200 of FIG. 2, the substrates 320 of FIGS. 3A and 3B, the device 400 of FIG. 4, or the device 530 of FIG. 5.

It should be noted that the method 600 of FIG. 6 may combine one or more processes in order to simplify and/or clarify the method for providing or fabricating an integrated circuit device. In some implementations, the order of the processes may be changed or modified.

The method 600 includes forming a first set of conductive structures extending from a first subset of off-package contacts of a substrate, at block 602. The substrate includes the off-package contacts and on-package contacts. For example, Stage 3 of FIG. 5B illustrates and describes examples of forming the conductive structures 512 on the off-package contacts 506B. The first set of conductive structures of the method 600 can include the conductive structures 108 of FIG. 1B, the conductive structures 408 of FIG. 4, or the conductive structures 512 of FIGS. 5B and 5C, and the first subset of off-package contacts of the method 600 can include the off-package contacts 114 of FIG. 1B, the off-package contacts 414 of FIG. 4, or the off-package contacts 506B of FIGS. 5A-5C. The on-package contacts of the method 600 can include the on-package contacts 110 of FIG. 1B, the on-package contacts 410 of FIG. 4, or the on-package contacts 504 of FIGS. 5A-5C, and the substrate of the method 600 can include the substrate 100 of FIGS. 1A and 1B, the substrate 200 of FIG. 2, the substrate 320A of FIG. 3B, the substrate 402 of FIG. 4, or the substrate 500 of FIGS. 5A-5C. Each off-package contact of the second subset of the off-package contacts may be adjacent to at least one edge of the substrate, as illustrated in FIG. 1B.

The method 600 includes electrically coupling a first set of electrical interconnects to a second subset of the off-package contacts to form a BGA, at block 604. For example, Stage 5 of FIG. 5C illustrates and describes examples of coupling the interconnects 520 to the off-package contacts 506A. The first set of electrical interconnects of the method 600 can include the interconnects 104 of FIGS. 1A and 1B, the interconnects 204 of FIG. 2, the interconnects 324 of FIG. 3B, the interconnects 404 of FIG. 4, or the interconnects 520 of FIG. 5C, and the second subset of the off-package contacts of the method 600 can include the off-package contacts 112 of FIG. 1B, the off-package contacts 412 of FIG. 4, or the off-package contacts 506A of FIGS. 5A-5C.

The method 600 includes electrically coupling a second set of electrical interconnects to the first set of conductive structures to form an LGA, at block 606. For example, Stage 5 of FIG. 5C illustrates and describes examples of coupling the interconnects 522 to the conductive structures 512. The second set of electrical interconnects of the method 600 can include the interconnects 106 of FIGS. 1A and 1B, the interconnects 206 of FIG. 2, the interconnects 326 of FIG. 3B, the interconnects 406 of FIG. 4, or the interconnects 522 of FIG. 5C. The LGA formed by the second set of electrical interconnects surrounds the BGA formed by the first set of electrical interconnects. In some implementations, forming the first set of conductive structures, electrically coupling the first set of electrical interconnects, and electrically coupling the second set of electrical interconnects are performed at a panel level of a fabrication process, such as a process to fabricate the device 530 of FIG. 5C.

In some implementations, forming the first set of conductive structures includes depositing one or more dielectric layers on a first region of a surface of the substrate that includes the first subset of the off-package contacts, forming one or more cavities that expose at least a portion of the first subset of the off-package contacts, and depositing a conductive material on the one or more dielectric layers and within the one or more cavities to form the first set of conductive structures. For example, Stage 2 of FIG. 5A illustrates and describes examples of depositing the additional dielectric layers 508 on the substrate 500 and the off-package contacts 506B and forming the cavities 510 that expose at least a portion of the off-package contacts 506B. As another example, Stage 3 of FIG. 5B illustrates and describes examples of depositing a conductive material within the cavities 510 to form the conductive structures 512. In some such implementations, the one or more dielectric layers include one or more photo-imageable dielectric materials or one or more solder resist materials.

In some implementations that include depositing the one or more dielectric layers, the method 600 may also include, prior to electrically coupling the first set of electrical interconnects and the second set of electrical interconnects, attaching one or more dies to the substrate and depositing a mold compound on the one or more dies and a second surface of the substrate. For example, Stage 4 of FIG. 5B illustrates and describes examples of attaching the die 516 to the substrate 500 (e.g., to the on-package contacts 504) and depositing the mold compound 518 on the die 516 and a top surface of the substrate 500. In such implementations, the method 600 also includes cutting, along a sawing street between a first package that includes the one or more dies and a second package, at least a portion of the substrate, at least a portion of the one or more dielectric layers, at least a portion of a conductive structure, and at least a portion of the mold compound. For example, Stage 6 of FIG. 5C illustrates and describes cutting at least a portion of the substrate 500, at least a portion of the additional dielectric layers 508, at least a portion of the conductive structures 512, and at least a portion of the mold compound 518 along the one or more sawing streets 524 to form the device 530. Additionally, or alternatively, electrically coupling the first set of electrical interconnects may include attaching a set of solder balls to the second subset of the off-package contacts and electrically coupling the second set of electrical interconnects may include depositing solder paste on the first set of conductive structures until a combined thickness of the solder paste and the first set of conductive structures is substantially the same as a thickness of the set of solder balls. For example, a thickness t1 of the interconnects 104 of FIG. 1B may be substantially the same as a combined thickness t3 of the conductive structures 108 and the interconnects 106.

In some implementations, the second set of electrical interconnects is configured to be coupled to a common ground via the substrate and a PCB. For example, one or more of the interconnects 406 of FIG. 4 may be coupled to a common ground via the substrate 402 and the PCB 430. Additionally, or alternatively, the second set of electrical interconnects may be configured to be coupled to a common source voltage via the substrate and a PCB. For example, one or more of the interconnects 406 of FIG. 4 may be coupled to a common source voltage via the substrate 402 and the PCB 430. Additionally, or alternatively, the second set of electrical interconnects may be configured to provide one or more signal pathways between the substrate and a PCB. For example, one or more of the interconnects 406 of FIG. 4 may be configured to provide one or more signal pathways between the substrate 402 and the PCB 430.

### Exemplary Electronic Devices

FIG. 7 illustrates various electronic devices that may include or be integrated with any of the substrate 100 (that includes multiple arrays of off-package interconnects), the substrate 200, the substrates 320, the device 400, or the device 530. For example, a mobile phone device 702, a laptop computer device 704, a fixed location terminal device 706, a wearable device 708, or a vehicle 710 (e.g., an automobile or an aerial device) may include a device 700. The device 700 can include, for example, any of the substrate 100, the substrate 200, the substrates 320, the device 400, or the device 530, and/or any other integrated device that includes a conductive structure described herein. The devices 702, 704, 706 and 708 and the vehicle 710 illustrated in FIG. 7 are merely exemplary. Other electronic devices may also feature the device 700 including, but not limited to, a group of devices (e.g., electronic devices) that includes mobile devices, hand-held personal communication systems (PCS) units, portable data units such as personal digital assistants, global positioning system (GPS) enabled devices, navigation devices, set top boxes, music players, video players, entertainment units, fixed location data units such as meter reading equipment, communications devices, smartphones, tablet computers, computers, wearable devices (e.g., watches, glasses), Internet of things (IoT) devices, servers, routers, electronic devices implemented in vehicles (e.g., autonomous vehicles), or any other device that stores or retrieves data or computer instructions, or any combination thereof.

One or more of the components, processes, features, and/or functions illustrated in FIGS. 1A-7 may be rearranged and/or combined into a single component, process, feature or function or embodied in several components, processes, or functions. Additional elements, components, processes, and/or functions may also be added without departing from the disclosure. It should also be noted FIGS. 1A-7 and their corresponding description in the present disclosure is not limited to dies and/or ICs. In some implementations, FIG. 1A-7 and their corresponding description may be used to manufacture, create, provide, and/or produce devices and/or integrated devices. In some implementations, a device may include a die, an integrated device, an embedded multi-chip package, an integrated passive device (IPD), a die package, an IC device, a device package, an IC package, a wafer, a semiconductor device, a package-on-package (PoP) device, a heat dissipating device and/or an interposer.

It is noted that the figures in the disclosure may represent actual representations and/or conceptual representations of various parts, components, objects, devices, packages, integrated devices, integrated circuits, and/or transistors. In some instances, the figures may not be to scale. In some instances, for purpose of clarity, not all components and/or parts may be shown. In some instances, the position, the location, the sizes, and/or the shapes of various parts and/or components in the figures may be exemplary. In some implementations, various components and/or parts in the figures may be optional.

The word “exemplary” is used herein to mean “serving as an example, instance, or illustration.” Any implementation or aspect described herein as “exemplary” is not necessarily to be construed as preferred or advantageous over other aspects of the disclosure. Likewise, the term “aspects” does not require that all aspects of the disclosure include the discussed feature, advantage or mode of operation. The term “coupled” is used herein to refer to the direct or indirect coupling (e.g., mechanical coupling) between two objects. For example, if object A physically touches object B, and object B touches object C, then objects A and C may still be considered coupled to one another—even if they do not directly physically touch each other. An object A, that is coupled to an object B, may be coupled to at least part of object B. The term “electrically coupled” may mean that two objects are directly or indirectly coupled together such that an electrical current (e.g., signal, power, ground) may travel between the two objects. Two objects that are electrically coupled may or may not have an electrical current traveling between the two objects. The use of the terms “first,” “second,” “third,” and “fourth” (and/or anything above fourth) is arbitrary. Any of the components described may be the first component, the second component, the third component or the fourth component. For example, a component that is referred to as a second component, may be the first component, the second component, the third component or the fourth component. The terms “encapsulate,” “encapsulating” and/or any derivation means that the object may partially encapsulate or completely encapsulate another object. The terms “top” and “bottom” are arbitrary. A component that is located on top may be located over a component that is located on a bottom. A top component may be considered a bottom component, and vice versa. As described in the disclosure, a first component that is located “over” a second component may mean that the first component is located above or below the second component, depending on how a bottom or top is arbitrarily defined. In another example, a first component may be located over (e.g., above) a first surface of the second component, and a third component may be located over (e.g., below) a second surface of the second component, where the second surface is opposite to the first surface. It is further noted that the term “over” as used in the present application in the context of one component located over another component, may be used to mean a component that is on another component and/or in another component (e.g., on a surface of a component or embedded in a component). Thus, for example, a first component that is over the second component may mean that (1) the first component is over the second component, but not directly touching the second component, (2) the first component is on (e.g., on a surface of) the second component, and/or (3) the first component is in (e.g., embedded in) the second component. A first component that is located “in” a second component may be partially located in the second component or completely located in the second component. A value that is about X-XX, may mean a value that is between X and XX, inclusive of X and XX. The value(s) between X and XX may be discrete or continuous. The term “about ‘value X’”, or “approximately ‘value X’”, as used in the disclosure means within 10 percent of the ‘value X’. For example, a value of about 1 or approximately 1, would mean a value in a range of 0.9-1.1. A “plurality” of components may include all the possible components or only some of the components from all of the possible components. For example, if a device includes ten components, the use of the term “the plurality of components” may refer to all ten components or only some of the components from the ten components.

In some implementations, an interconnect is an element or component of a device or package that allows or facilitates an electrical connection between two points, elements and/or components. In some implementations, an interconnect may include a trace, a via, a pad, a pillar, a metallization layer, a redistribution layer, and/or an under bump metallization (UBM) layer/interconnect. In some implementations, an interconnect may include an electrically conductive material that may be configured to provide an electrical path for a signal (e.g., a data signal), ground and/or power. An interconnect may include more than one element or component. An interconnect may be defined by one or more interconnects. An interconnect may include one or more metal layers. An interconnect may be part of a circuit. Different implementations may use different processes and/or sequences for forming the interconnects. In some implementations, a chemical vapor deposition (CVD) process, a physical vapor deposition (PVD) process, a sputtering process, a spray coating, and/or a plating process may be used to form the interconnects.

Also, it is noted that various disclosures contained herein may be described as a process that is depicted as a flowchart, a flow diagram, a structure diagram, or a block diagram. Although a flowchart may describe the operations as a sequential process, many of the operations can be performed in parallel or concurrently. In addition, the order of the operations may be re-arranged. A process is terminated when its operations are completed.

In the following, further examples are described to facilitate the understanding of the disclosure.

According to Example 1, an integrated device includes: one or more dies and a substrate that includes: on-package contacts coupled to the one or more dies; and off-package contacts configured to be coupled to a printed circuit board (PCB). The integrated device also includes: a first set of electrical interconnects electrically coupled to a first subset of the off-package contacts and that form a ball grid array (BGA); and a second set of electrical interconnects electrically coupled to a second subset of the off-package contacts and that form a land grid array (LGA).

Example 2 includes the integrated device of Example 1, where each off-package contact of the second subset of the off-package contacts is adjacent to at least one edge of the substrate.

Example 3 includes the integrated device of Example 1 or Example 2, where the LGA surrounds the BGA.

Example 4 includes the device of any of Examples 1 to 3, where: one or more off-package contacts of the first subset of the off-package contacts are disposed at least partially between a first off-package contact of the second subset of the off-package contacts and a second off-package contact of the second subset of the off-package contacts; the first off-package contact is disposed at least partially between the one or more off-package contacts and a first edge of the substrate; and the second off-package contact is disposed at least partially between the one or more off-package contacts and a second edge of the substrate.

Example 5 includes the integrated device of any of Examples 1 to 4, where a first thickness of a first electrical interconnect of the first set of electrical interconnects with respect to a first axis that is geometrically normal to the substrate and that extends through the first electrical interconnect is greater than a second thickness of a second electrical interconnect of the second set of electrical interconnects with respect to a second axis that is geometrically normal to the substrate and that extends through the second electrical interconnect.

Example 6 includes the integrated device of any of Examples 1 to 5, where: the first subset of the off-package contacts is disposed within a first region on a first surface of the substrate, where the first region has a first number of layers between the first surface and a second surface of the substrate that is opposite to the first surface; and the second subset of the off-package contacts is disposed within a second region on the first surface, where the second region has a second number of layers between the first surface and the second surface that is greater than the first number.

Example 7 includes the integrated device of any of Examples 1 to 6, where the first set of electrical interconnects includes a set of solder balls, and where the second set of electrical interconnects includes a set of substantially planar solder structures.

Example 8 includes the integrated device of any of Examples 1 to 7, where the second set of electrical interconnects is configured to be coupled to a common ground via the substrate and the PCB.

Example 9 includes the integrated device of any of Examples 1 to 7, where the second set of electrical interconnects is configured to be coupled to a common source voltage via the substrate and the PCB.

Example 10 includes the integrated device of any of Examples 1 to 7, where the second set of electrical interconnects is configured to provide one or more signal pathways between the substrate and the PCB.

According to Example 11 a method of fabrication includes: forming a first set of conductive structures extending from a first subset of off-package contacts of a substrate, the substrate including the off-package contacts and on-package contacts; electrically coupling a first set of electrical interconnects to a second subset of the off-package contacts to form a ball grid array (BGA); and electrically coupling a second set of electrical interconnects to the first set of conductive structures to form a land grid array (LGA).

Example 12 includes the method of Example 11, where said forming the first set of conductive structures includes: depositing one or more dielectric layers on a first region of a surface of the substrate that includes the first subset of the off-package contacts; forming one or more cavities that expose at least a portion of the first subset of the off-package contacts; and depositing a conductive material on the one or more dielectric layers and within the one or more cavities to form the first set of conductive structures.

Example 13 includes the method of Example 12, where the one or more dielectric layers include one or more photo-imageable dielectric materials.

Example 14 includes the method of Example 12, where the one or more dielectric layers include one or more solder resist materials.

Example 15 includes the method of any of Examples 12 to 14, and further includes: prior to electrically coupling the first set of electrical interconnects and the second set of electrical interconnects, attaching one or more dies to the substrate and depositing a mold compound on the one or more dies and a second surface of the substrate; and cutting, along a sawing street between a first package that includes the one or more dies and a second package, at least a portion of the substrate, at least a portion of the one or more dielectric layers, at least a portion of a conductive structure, and at least a portion of the mold compound.

Example 16 includes the method of any of Examples 12 to 15, where: electrically coupling the first set of electrical interconnects includes attaching a set of solder balls to the second subset of the off-package contacts; and electrically coupling the second set of electrical interconnects includes depositing solder paste on the first set of conductive structures until a combined thickness of the solder paste and the first set of conductive structures is substantially the same as a thickness of the set of solder balls.

Example 17 includes the method of any of Examples 11 to 16, where said forming the first set of conductive structures, said electrically coupling the first set of electrical interconnects, and said electrically coupling the second set of electrical interconnects are performed at a panel level of a fabrication process.

According to Example 18, a device includes: one or more dies; a printed circuit board (PCB); and a substrate disposed between the one or more dies and the PCB. The substrate includes: on-package contacts coupled to the one or more dies; and off-package contacts coupled to the PCB. The device also includes: a first set of electrical interconnects electrically coupled to a first subset of the off-package contacts and to the PCB and that form a ball grid array (BGA); and a second set of electrical interconnects electrically coupled to a second subset of the off-package contacts and to the PCB and that form a land grid array (LGA).

Example 19 includes the device of Example 18, where: a first distance between a first point on a first surface of the substrate and a corresponding first point on a surface of the PCB is substantially the same as a second distance between a second point on the first surface of the substrate and a corresponding second point on the surface of the PCB; the first surface of the substrate includes the on-package contacts; a first electrical interconnect of the first set of electrical interconnects is disposed between the first point on the first surface of the substrate and the corresponding first point on the surface of the PCB; and a second electrical interconnect of the second set of electrical interconnects is disposed between the second point on the first surface of the substrate and the corresponding second point on the surface of the PCB.

Example 20 includes the device of Example 18 or Example 19, where: the first set of electrical interconnects provides one or more signal pathways between the substrate and the PCB; and the second set of electrical interconnects is coupled to a common ground or a common source voltage via the substrate and the PCB.

The various features of the disclosure described herein can be implemented in different systems without departing from the disclosure. It should be noted that the foregoing aspects of the disclosure are merely examples and are not to be construed as limiting the disclosure. The description of the aspects of the present disclosure is intended to be illustrative, and not to limit the scope of the claims. As such, the present teachings can be readily applied to other types of apparatuses and many alternatives, modifications, and variations will be apparent to those skilled in the art.

What is claimed is:

1. An integrated device comprising:
one or more dies;
a substrate that includes:
on-package contacts coupled to the one or more dies; and
off-package contacts configured to be coupled to a printed circuit board (PCB);
a first set of electrical interconnects electrically coupled to a first subset of the off-package contacts and that form a ball grid array (BGA); and
a second set of electrical interconnects electrically coupled to a second subset of the off-package contacts and that form a land grid array (LGA).

2. The integrated device of claim 1, wherein each off-package contact of the second subset of the off-package contacts is adjacent to at least one edge of the substrate.

3. The integrated device of claim 1, wherein the LGA surrounds the BGA.

4. The integrated device of claim 1, wherein:
one or more off-package contacts of the first subset of the off-package contacts are disposed at least partially between a first off-package contact of the second subset of the off-package contacts and a second off-package contact of the second subset of the off-package contacts;
the first off-package contact is disposed at least partially between the one or more off-package contacts and a first edge of the substrate; and
the second off-package contact is disposed at least partially between the one or more off-package contacts and a second edge of the substrate.

5. The integrated device of claim 1, wherein a first thickness of a first electrical interconnect of the first set of electrical interconnects with respect to a first axis that is geometrically normal to the substrate and that extends through the first electrical interconnect is greater than a second thickness of a second electrical interconnect of the second set of electrical interconnects with respect to a second axis that is geometrically normal to the substrate and that extends through the second electrical interconnect.

6. The integrated device of claim 1, wherein:
the first subset of the off-package contacts is disposed within a first region on a first surface of the substrate, wherein the first region has a first number of layers between the first surface and a second surface of the substrate that is opposite to the first surface; and
the second subset of the off-package contacts is disposed within a second region on the first surface, wherein the second region has a second number of layers between the first surface and the second surface that is greater than the first number.

7. The integrated device of claim 1, wherein the first set of electrical interconnects includes a set of solder balls, and wherein the second set of electrical interconnects includes a set of substantially planar solder structures.

8. The integrated device of claim 1, wherein the second set of electrical interconnects is configured to be coupled to a common ground via the substrate and the PCB.

9. The integrated device of claim 1, wherein the second set of electrical interconnects is configured to be coupled to a common source voltage via the substrate and the PCB.

10. The integrated device of claim 1, wherein the second set of electrical interconnects is configured to provide one or more signal pathways between the substrate and the PCB.

11. A method comprising:
forming a first set of conductive structures extending from a first subset of off-package contacts of a substrate, the substrate including the off-package contacts and on-package contacts;
electrically coupling a first set of electrical interconnects to a second subset of the off-package contacts to form a ball grid array (BGA); and
electrically coupling a second set of electrical interconnects to the first set of conductive structures to form a land grid array (LGA).

12. The method of claim 11, wherein said forming the first set of conductive structures includes:
depositing one or more dielectric layers on a first region of a surface of the substrate that includes the first subset of the off-package contacts;
forming one or more cavities that expose at least a portion of the first subset of the off-package contacts; and
depositing a conductive material on the one or more dielectric layers and within the one or more cavities to form the first set of conductive structures.

13. The method of claim 12, wherein the one or more dielectric layers include one or more photo-imageable dielectric materials.

14. The method of claim 12, wherein the one or more dielectric layers include one or more solder resist materials.

15. The method of claim 12, further comprising:
prior to electrically coupling the first set of electrical interconnects and the second set of electrical interconnects, attaching one or more dies to the substrate and depositing a mold compound on the one or more dies and a second surface of the substrate; and
cutting, along a sawing street between a first package that includes the one or more dies and a second package, at least a portion of the substrate, at least a portion of the one or more dielectric layers, at least a portion of a conductive structure, and at least a portion of the mold compound.

16. The method of claim 12, wherein:
electrically coupling the first set of electrical interconnects includes attaching a set of solder balls to the second subset of the off-package contacts; and
electrically coupling the second set of electrical interconnects includes depositing solder paste on the first set of conductive structures until a combined thickness of the solder paste and the first set of conductive structures is substantially the same as a thickness of the set of solder balls.

17. The method of claim 11, wherein said forming the first set of conductive structures, said electrically coupling the first set of electrical interconnects, and said electrically coupling the second set of electrical interconnects are performed at a panel level of a fabrication process.

18. A device comprising:
one or more dies;
a printed circuit board (PCB);
a substrate disposed between the one or more dies and the PCB, wherein the substrate includes:
on-package contacts coupled to the one or more dies; and
off-package contacts coupled to the PCB;
a first set of electrical interconnects electrically coupled to a first subset of the off-package contacts and to the PCB and that form a ball grid array (BGA); and
a second set of electrical interconnects electrically coupled to a second subset of the off-package contacts and to the PCB and that form a land grid array (LGA).

19. The device of claim 18, wherein:
a first distance between a first point on a first surface of the substrate and a corresponding first point on a surface of the PCB is substantially the same as a second distance between a second point on the first surface of the substrate and a corresponding second point on the surface of the PCB;
the first surface of the substrate includes the on-package contacts;
a first electrical interconnect of the first set of electrical interconnects is disposed between the first point on the first surface of the substrate and the corresponding first point on the surface of the PCB; and
a second electrical interconnect of the second set of electrical interconnects is disposed between the second point on the first surface of the substrate and the corresponding second point on the surface of the PCB.

20. The device of claim 18, wherein:
the first set of electrical interconnects provides one or more signal pathways between the substrate and the PCB; and
the second set of electrical interconnects is coupled to a common ground or a common source voltage via the substrate and the PCB.
